(19) United States
(12) Patent Application Publication
(10) Pub. No.: US 2026/0006975 A1
(43) Pub. Date: Jan. 1, 2026

(54) DISPLAY DEVICE

(71) Applicant: AUO Corporation, Hsinchu City (TW)

(72) Inventors: Kuo-Lung LO, Hsinchu City (TW); Hui-Ku CHANG, Hsinchu City (TW); Tsung-Yu WU, Hsinchu City (TW); Chun-Hong LIN, Hsinchu City (TW); Jhih-Yuan SU, Hsinchu City (TW)

(21) Appl. No.: 18/960,879

(22) Filed: Nov. 26, 2024

(30) Foreign Application Priority Data
Jun. 27, 2024 (TW) 113124120

(51) Int. Cl. H10H 29/85; H10H 29/80

(52) U.S. Cl. CPC H10H 29/857; H10H 29/942

(57) ABSTRACT

A display device includes multiple layout units arranged in array and multiple light emitting elements disposed in the layout units. Each layout unit includes multiple pixel units, multiple repair units and a common electrode. Each pixel unit includes multiple sub-pixel units, and each sub-pixel unit includes a pixel electrode. One of the repair units is used to repair any one of three of the sub-pixel units, and each repair unit includes a repair electrode. In each layout unit, the number of the repair electrodes is smaller than the number of the pixel electrodes. Each light emitting element includes a first pad electrically connected to the pixel electrode or the repair electrode, and a second pad electrically connected to the common electrode. The light emitting elements have a shortest connecting line between the first pad and the second pad apiece while the shortest connecting lines are parallel to each other.

### CROSS-REFERENCE TO RELATED APPLICATION

This application claims priority to Taiwan Application Serial Number 113124120, filed Jun. 27, 2024, which is herein incorporated by reference in its entirety.

### BACKGROUND

### Field of Invention

The present disclosure relates to a display device. More particularly, the present disclosure relates to a display device including multiple light emitting elements and multiple repair units.

### Description of Related Art

Micro light emitting diode (micro LED) display device is a kind of flat panel display (FPD) including light emitting diodes with size from 1 to 100 micrometers. Compared with liquid crystal display devices, micro LED display devices have higher contrast, faster response time, and consume less power. With the technological advancement of the optoelectronic industry, the size of optoelectronic components is gradually becoming smaller. Therefore, micro LED display devices have become the mainstream in the display device industry.

Generally, the yield of micro LEDs is not yet perfect, and after inspection of micro LEDs installed on the backplane and connected to electrodes, a small number of sub-pixel defects can still be found. The existing way to resolve sub-pixel defects is to place a repair unit correspondingly next to the original sub-pixel unit, and the repair unit can only repair the specific sub-pixel unit. However, the actual chance of using the repair unit for repairing is not high, and the layout space of the backplane is limited. The aforementioned one-to-one arrangement of sub-pixel units and repair units will cause a reduction in the display area ratio and resolution.

### SUMMARY

At least one embodiment of the present disclosure provides a display device in which one repair unit in the layout unit can repair any one of three sub-pixel units, thereby reducing the number of repair units and increasing the display area ratio and the resolution.

The display device according to at least one embodiment of the present disclosure includes multiple layout units and multiple light emitting elements. The layout units are arranged in array, and each of the layout units includes multiple pixel units, multiple repair units and a common electrode. Each of the pixel units includes multiple sub-pixel units, and each of the sub-pixel units includes a pixel electrode. One of the repair units is used to repair any one of three of the sub-pixel units, and each of the repair units includes a repair electrode. In each of the layout units, the number of the repair electrodes is smaller than the number of the pixel electrodes. The light emitting elements are disposed in the layout units, each of the light emitting elements includes a first pad electrically connected to the pixel electrode or the repair electrode, and a second pad electrically connected to the common electrode. The light emitting elements have a shortest connecting line between the first pad and the second pad apiece while the shortest connecting lines are parallel to each other.

The display device according to at least another embodiment of the present disclosure includes multiple layout units and multiple light emitting elements. The layout units are arranged in array, and each of the layout units includes multiple pixel units, multiple repair units and a common electrode. Each of the pixel units includes multiple sub-pixel units, and each of the sub-pixel units includes a pixel electrode. One of the repair units is used to repair any one of three of the sub-pixel units, and each of the repair units includes a repair electrode. In each of the layout units, the ratio of the number of the repair electrodes to the number of the pixel electrodes is 0.6. The light emitting elements are disposed in the layout units, each of the light emitting elements includes a first pad electrically connected to the pixel electrode or the repair electrode, and a second pad electrically connected to the common electrode. The light emitting elements have a shortest connecting line between the first pad and the second pad apiece while the shortest connecting lines are parallel to each other.

### BRIEF DESCRIPTION OF THE DRAWINGS

FIG. 1 is a layout diagram of a display device according to at least one embodiment of the present disclosure.

FIG. 2A is an enlarged diagram of region A in FIG. 1.

FIG. 2B to FIG. 2D are enlarged diagrams of partial areas of display devices according to at least another embodiment of the present disclosure.

FIG. 3A to FIG. 3D are schematic diagrams of a repair method for a display device in different stages according to at least one embodiment of the present disclosure.

FIG. 4A and FIG. 4B are schematic diagrams of a repair method for a display device according to at least another embodiment of the present disclosure.

FIG. 5A to FIG. 5D are schematic diagrams of a repair method for a display device according to at least another embodiment of the present disclosure.

FIG. 6A and FIG. 6B are schematic diagrams of a repair method for a display device according to at least another embodiment of the present disclosure.

FIG. 7A to FIG. 7C are schematic diagrams of a repair method for a display device according to at least another embodiment of the present disclosure.

FIG. 8 is an enlarged diagram of partial area of a display device according to at least another embodiment of the present disclosure.

FIG. 9 is a schematic partial cross-sectional diagram of a display device according to at least another embodiment of the present disclosure.

FIG. 10A and FIG. 10B are enlarged diagrams of partial areas of display devices according to at least another embodiment of the present disclosure.

### DETAILED DESCRIPTION

In the following description, in order to clearly present the technical features of the present disclosure, the dimensions (such as length, width, thickness, and depth) of elements (such as layers, films, substrates, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

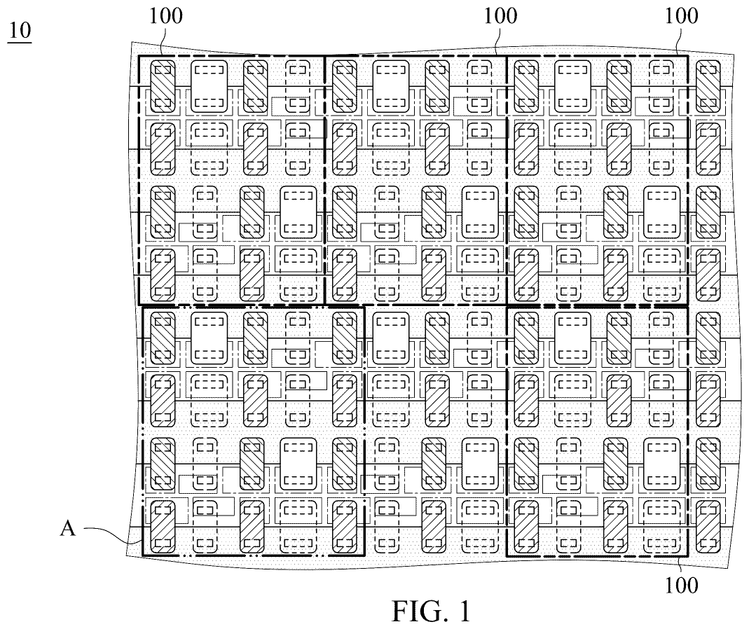

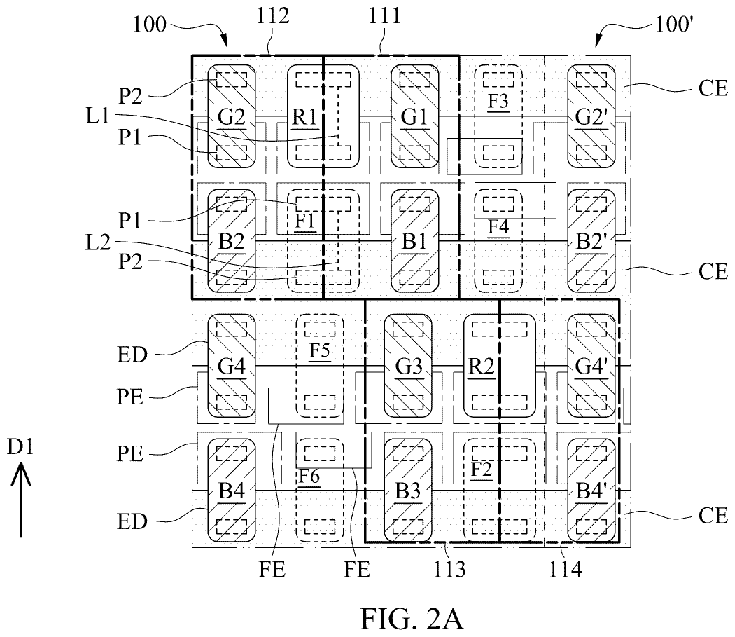

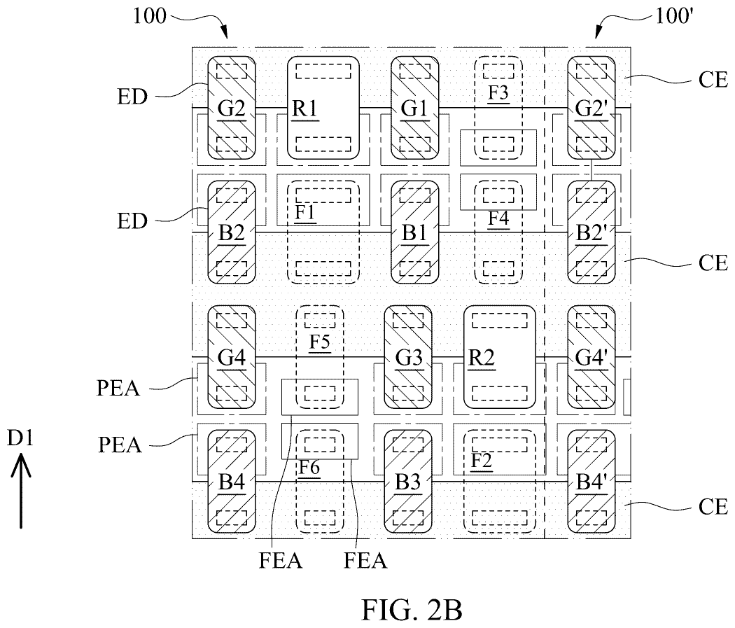

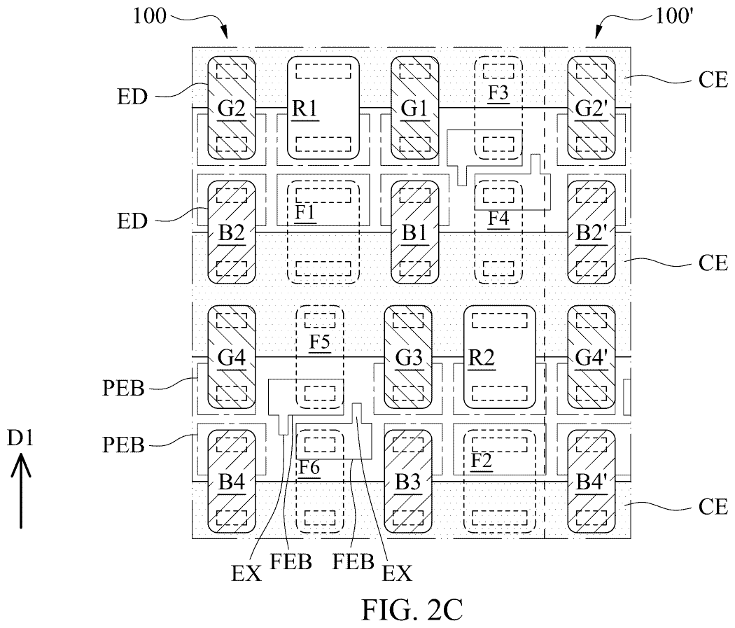

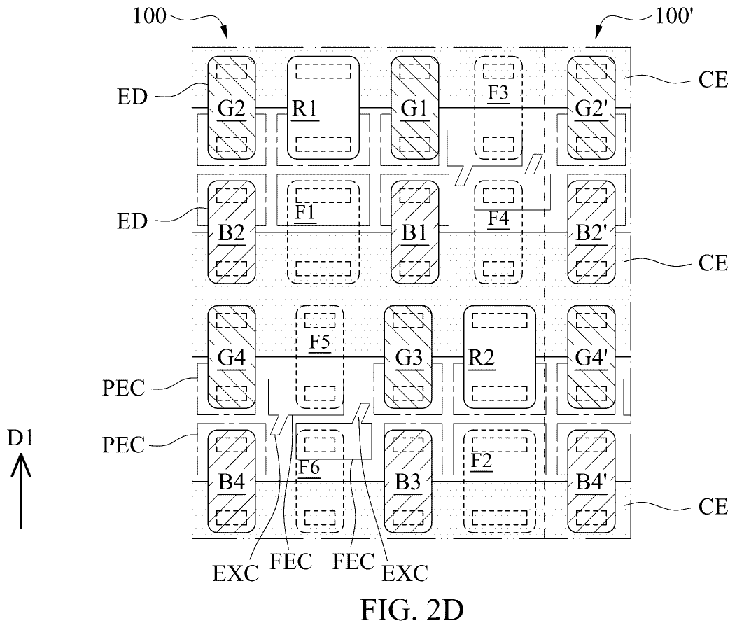

FIG. 1 is a layout diagram of a display device 10 according to at least one embodiment of the present disclosure. FIG. 2A is an enlarged diagram of region A in FIG. 1. Referring to FIG. 1 and FIG. 2A, the display device 10 includes multiple layout units 100 and multiple light emitting elements ED. The layout units 100 are arranged in array, and each of the layout unit 100 includes multiple pixel units 111, 112, 113, 114, multiple repair units F1, F2, F3, F4, F5, F6, and a common electrode CE. It should be understood that although FIG. 1 merely illustrates six layout units, the present disclosure is not limited thereto. In other embodiments, the number of layout units can be increased or reduced according to the size of the display device.

Each of the pixel unit includes multiple sub-pixel units. For example, the pixel unit 111 includes multiple sub-pixel units R1, G1, B1, the pixel unit 112 includes multiple sub-pixel units R1, G2, B2, the pixel unit 113 includes multiple sub-pixel units R2, G3, B3, and the pixel unit 114 includes multiple sub-pixel units R2, G4′, B4′. Each of the sub-pixel units R1, G1, B1, G2, B2, R2, G3, B3, G4′, B4′ includes a pixel electrode PE.

As shown in FIG. 2A, one of the repair units is used to repair any one of three of the sub-pixel units. For example, the repair unit F1 is used to repair any one of three of the sub-pixel units R1, B1, B2, the repair unit F2 is used to repair any one of three of the sub-pixel units R2, B3, B4′, the repair unit F3 is used to repair any one of three of the sub-pixel units G1, G2′, B1, the repair unit F4 is used to repair any one of three of the sub-pixel units G2′, B1, B2′, the repair unit F5 is used to repair any one of three of the sub-pixel units G3, G4, B4, and the repair unit F6 is used to repair any one of three of the sub-pixel units G3, B3, B4.

Each of the repair units F1, F2, F3, F4, F5, F6 includes a repair electrode FE. In each of the layout units 100, the number of the repair electrodes FE is smaller than the number of the pixel electrodes PE. For example, as shown in FIG. 2A, in the layout unit 100, the number of the repair electrodes FE is six, and the number of the pixel electrodes PE is ten. That is, in the layout unit 100, the ratio of the number of the repair electrodes FE to the number of the pixel electrodes PE is 0.6.

The light emitting elements ED are disposed in the layout unit 100. Each of the light emitting elements ED includes a first pad P1 electrically connected to the pixel electrode PE or the repair electrode FE, and a second pad P2 electrically connected to the common electrode CE. The light emitting elements ED have a shortest connecting line between the first pad P1 and the second pad P2 apiece while the shortest connecting lines are parallel to each other. For example, as shown in FIG. 2A, the shortest connecting lines L1, L2 between the first pad P1 and the second pad P2 of each of the light emitting elements ED are substantially parallel to a first direction D1.

One of the repair units is used to repair any one of three of the sub-pixel units, and in each of the layout units, the number of the repair electrodes is smaller than the number of the pixel electrodes, so the number of the repair units and the number of the repair electrodes can be reduced, thereby increasing the display area ratio and the resolution. Furthermore, since the shortest connecting lines between the first pads electrically connected to the pixel electrodes or the repair electrodes and the second pads electrically connected to the common electrodes are parallel to each other, that is, the light emitting elements are arranged in an array of regular rows and columns, which can reduce the difficulty of manufacturing and repair and is suitable for mass transfer.

Referring to FIG. 1 and FIG. 2A, in each layout unit 100, the sub-pixel units R1, G1, B1, R2, G2, B2, G3, B3, G4, B4 and the repair units F1, F2, F3, F4, F5, F6 are arranged in array. In some embodiments, the outline of each layout unit 100 is substantially rectangular.

Each pixel unit 111, 112, 113, 114 includes a first sub-pixel unit R1, R2, a second sub-pixel unit G1, G2, G3, G4′, and a third sub-pixel unit B1, B2, B3, B4′. The pixel units include a first pixel unit 111, a second pixel unit 112, a third pixel unit 113, and a fourth pixel unit 114. In two of the layout units 100, 100′ adjacent to each other, the first pixel unit 111 and the second pixel unit 112 of one of the two of the layout units (i.e. the layout unit 100) share one of the first sub-pixel units (i.e. the first sub-pixel unit R1), and the third pixel unit 113 of the one of the two of the layout units (i.e. the layout unit 100) and the fourth pixel unit 114 of the other of the two of the layout units (i.e. the layout unit 100′) share the other of the first sub-pixel units (i.e. the first sub-pixel unit R2). In other words, two pixel units share the same light emitting element disposed in the same first sub-pixel unit, that is, one pixel unit has 2.5 light emitting elements. The aforementioned design can be applied to the products that require higher current for the specific color sub-pixel units.

In some embodiments, the first sub-pixel units R1, R2 may be red, the second sub-pixel units G1, G2, G3, G4′ may be green, and the third sub-pixel units B1, B2, B3, B4′ may be blue, but the present disclosure is not limited thereto. The luminous area of each of the light emitting elements ED disposed in the first sub-pixel units R1, R2 is larger than the luminous area of each of the light emitting elements ED disposed in the second sub-pixel units G1, G2, G3, G4′ and/or the luminous area of each of the light emitting elements ED disposed in the third sub-pixel units B1, B2, B3, B4′.

The light emitting element ED may be a light emitting diode (LED), which is, for example, a sub-millimeter light emitting diode (mini LED) or a micro light emitting diode (micro LED, μLED). The micro LED has a thickness less than 10 micrometers, e.g., 6 micrometers. The sub-millimeter LEDs can be categorized into two types: one including a package and the other not including a package. The thickness of the sub-millimeter light emitting diode including the package can be less than 800 micrometers, and the thickness of the sub-millimeter light emitting diode not including the package may be less than 100 micrometers. In addition, the light emitting element ED may also be a large size regular light emitting diode (regular LED) other than the sub-millimeter light emitting diode and the micro light emitting diode, so that the light emitting element ED is not limited to the sub-millimeter light emitting diode or the micro light emitting diode.

As shown in FIG. 2A, in two of the layout units 100, 100′ adjacent to each other, the repair units include a first repair unit F1 for repairing one of the first sub-pixel R1 of the first pixel unit 111 of the one of the two layout units (i.e. the layout unit 100), the third sub-pixel unit B1 of the first pixel unit 111 of the one of the two layout units (i.e. the layout unit 100), and the third sub-pixel unit B2 of the second pixel unit 112 of the one of the two layout units (i.e. the layout unit 100).

The repair units include a second repair unit F2 for repairing one of the first sub-pixel R2 of the third pixel unit 113 of the one of the two layout units (i.e. the layout unit 100), the third sub-pixel unit B3 of the third pixel unit 113 of the one of the two layout units (i.e. the layout unit 100), and the third sub-pixel unit B4′ of the fourth pixel unit 114 of the other of the two layout units (i.e. the layout unit 100′).

The repair units include a third repair unit F3 for repairing one of the second sub-pixel G1 of the first pixel unit 111 of the one of the two layout units (i.e. the layout unit 100), the third sub-pixel unit B1 of the first pixel unit 111 of the one of the two layout units (i.e. the layout unit 100), and the second sub-pixel unit G2′ of the second pixel unit 112 of the other of the two layout units (i.e. the layout unit 100′).

The repair units include a fourth repair unit F4 for repairing one of the third sub-pixel B1 of the first pixel unit 111 of the one of the two layout units (i.e. the layout unit 100), the second sub-pixel unit G2′ of the second pixel unit 112 of the other of the two layout units (i.e. the layout unit 100′), and the third sub-pixel unit B2′ of the second pixel unit 112 of the other of the two layout units (i.e. the layout unit 100′).

The repair units include a fifth repair unit F5 for repairing one of the second sub-pixel G3 of the third pixel unit 113 of the one of the two layout units (i.e. the layout unit 100), the second sub-pixel unit G4 of the fourth pixel unit 114 of the one of the two layout units (i.e. the layout unit 100), and the third sub-pixel unit B4 of the fourth pixel unit 114 of the one of the two layout units (i.e. the layout unit 100).

The repair units include a sixth repair unit F6 for repairing one of the second sub-pixel G3 of the third pixel unit 113 of the one of the two layout units (i.e. the layout unit 100), the third sub-pixel unit B3 of the third pixel unit 113 of the one of the two layout units (i.e. the layout unit 100), and the third sub-pixel unit B4 of the fourth pixel unit 114 of the one of the two layout units (i.e. the layout unit 100).

As shown in FIG. 2A, in each layout unit 100, two of the repair electrodes FE (e.g. the repair electrodes FE of the repair units F5, F6) are arranged adjacently in the first direction D1, and a portion of the two of the repair electrodes FE (e.g. the repair electrodes FE of the repair units F5, F6) do not overlap in the first direction D1. In addition, in the first direction D1, the aforementioned portion of the two of the repair electrodes FE (e.g. the repair electrodes FE of the repair units F5, F6) overlap with two of the pixel electrodes PE (e.g. the pixel electrodes PE of the sub-pixel units G3, B4), respectively.

In detail, the pixel electrode PE of the sub-pixel unit G3 adjacent to the repair unit F5 protrudes from the pixel electrode PE of the sub-pixel unit B3 adjacently arranged in the first direction D1, and the protruding portion overlaps with the repair electrode FE of the repair unit F6. The pixel electrode PE of the sub-pixel unit B4 adjacent to the repair unit F6 protrudes from the pixel electrode PE of the sub-pixel unit G4 adjacently arranged in the first direction D1, and the protruding portion overlaps with the repair electrode FE of the repair unit F5.

Through the design that a portion of the two of the repair electrodes FE do not overlap in the first direction D1, the risk of the repair unit short-circuiting with other sub-pixel units when repairing oblique sub-pixel unit can be reduced.

FIG. 2B to FIG. 2D are enlarged diagrams of partial areas of display devices according to at least another embodiment of the present disclosure. Referring to FIG. 2B to FIG. 2D, the structures and the relative positions of most elements in the display devices of FIG. 2B to FIG. 2D and the display device 10 of FIG. 2A are the same, so the same features are not repeated here.

The difference between the embodiment of FIG. 2B and the embodiment of FIG. 2A is that in each layout unit 100, two of the repair electrodes FEA of FIG. 2B (e.g. the repair electrodes FEA of the repair units F5, F6) are arranged adjacently in the first direction D1, and the two of the repair electrodes FEA (e.g. the repair electrodes FEA of the repair units F5, F6) substantially completely overlap in the first direction D1. That is, in the first direction D1, the edges of the two of the repair electrodes FEA (e.g. the repair electrodes FEA of the repair units F5, F6) are substantially flush with each other. In addition, in each layout unit 100, two of the pixel electrodes PEA of FIG. 2B (e.g. the pixel electrodes PEA of the sub-pixel units G4, B4) are arranged adjacently in the first direction D1, and the two of the pixel electrodes PEA (e.g. the pixel electrodes PEA of the sub-pixel units G4, B4) substantially completely overlap in the first direction D1. That is, in the first direction D1, the edges of the two of the pixel electrodes PEA (e.g. the pixel electrodes PEA of the sub-pixel units G4, B4) are substantially flush with each other.

The difference between the embodiment of FIG. 2C and the embodiment of FIG. 2A is that two of the repair electrodes FEB (e.g. the repair electrodes FEB of the repair units F5, F6) include extending parts EX, respectively, and one of the two extending parts EX (e.g. the extending part EX of the repair electrode FEB of the repair unit F6) substantially extends in the first direction D1, and the other of the two extending parts EX (e.g. the extending part EX of the repair electrode FEB of the repair unit F5) substantially extends in a direction that is 180 degrees from the first direction D1. In addition, in the first direction D1, the non-overlapping portions of the two repair electrodes FEB do not overlap with the two pixel electrodes PEB (e.g. the pixel electrodes PEB of the sub-pixel units G3, B4) respectively, but the present disclosure is not limited thereto. In other embodiments, in the first direction D1, the non-overlapping portions of the two repair electrodes FEB may overlap with the two pixel electrodes PEB (e.g. the pixel electrodes PEB of the sub-pixel units G3, B4), respectively.

The difference between the embodiment of FIG. 2D and the embodiment of FIG. 2A is that two of the repair electrodes FEC (e.g. the repair electrodes FEC of the repair units F5, F6) include extending parts EXC, respectively, and one of the two extending parts EXC (e.g. the extending part EXC of the repair electrode FEC of the repair unit F6) substantially extends in a direction that is greater than 0 degrees and less than 90 degrees from the first direction D1, and the other of the two extending parts EXC (e.g. the extending part EXC of the repair electrode FEC of the repair unit F5) substantially extends in a direction that is greater than 180 degrees and less than 270 degrees from the first direction D1. In addition, in the first direction D1, the non-overlapping portions of the two repair electrodes FEC do not overlap with the two pixel electrodes PEC (e.g. the pixel electrodes PEC of the sub-pixel units G3, B4), respectively, but the present disclosure is not limited thereto. In other embodiments, in the first direction D1, the non-overlapping portions of the two repair electrodes FEC may overlap with the two pixel electrodes PEC (e.g. the pixel electrodes PEC of the sub-pixel units G3, B4) respectively.

Through the design that the repair electrodes include extending parts, the risk of the repair unit short-circuiting with other sub-pixel units when repairing oblique sub-pixel unit can be reduced.

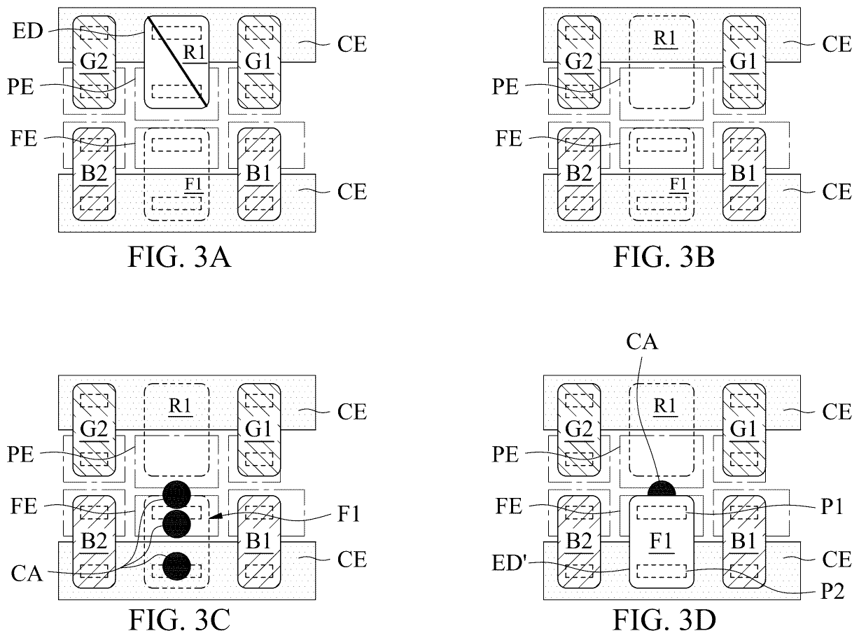

FIG. 3A to FIG. 3D are schematic diagrams of a repair method for a display device in different stages according to at least one embodiment of the present disclosure. Referring to FIG. 3A to FIG. 3D, the repair method of the display device 10 includes the following steps. First, as shown in FIG. 3A, the light emitting element disposed in each sub-pixel unit is detected to be defective, and if the light emitting element is detected to be defective, for example, the light emitting element ED disposed in the first sub-pixel unit R1 of the first pixel unit 111 is detected to be defective, as shown in FIG. 3B, the light emitting element is removed, for example, the light emitting element ED of the first subpixel unit R1 of the first pixel unit 111 is removed. Next, as shown in FIG. 3C, conductive adhesives CA are provided between the pixel electrode of the aforementioned sub-pixel unit and the repair electrode of the repair unit, on the repair electrode of the repair unit, and on the common electrode CE, for example, conductive adhesives CA are provided between the pixel electrode PE of the first sub-pixel unit R1 of the first pixel unit 111 and the repair electrode FE of the first repair unit F1, on the repair electrode FE of the first repair unit F1, and on the common electrode CE. As shown in FIG. 3D, a light emitting element ED′ for replacement is provided on the aforementioned conductive adhesives CA. For example, the first pad P1 of the light emitting element ED′ is electrically connected to the conductive adhesive CA provided on the repair electrode FE of the first repair unit F1, so that the first pad P1 of the light emitting element ED′ is electrically connected to the repair electrode FE of the first repair unit F1, and the second pad P2 of the light emitting element ED′ is electrically connected to the conductive adhesive CA provided on the common electrode CE, so that the second pad P2 of the light emitting element ED′ is electrically connected to the common electrode CE.

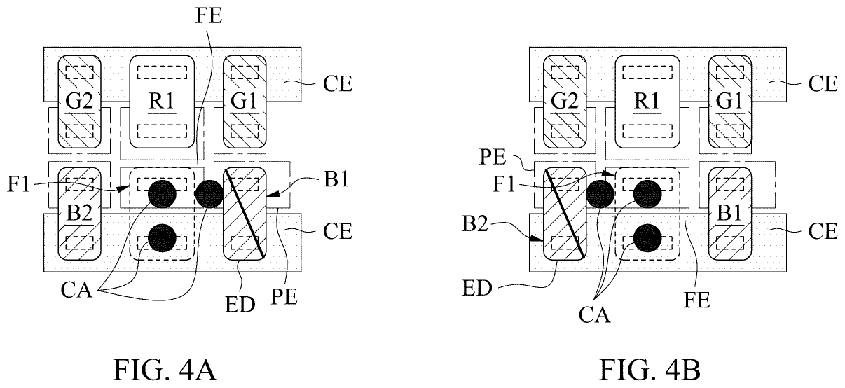

FIG. 4A and FIG. 4B are schematic diagrams of a repair method for a display device according to at least another embodiment of the present disclosure. FIG. 3A to FIG. 3D illustrate how the first repair unit F1 repairs the first sub-pixel unit R1 of the first pixel unit 111. FIG. 4A illustrates how the first repair unit F1 repairs the third sub-pixel unit B1 of the first pixel unit 111, and FIG. 4B illustrates how the first repair unit F1 repairs the third sub-pixel unit B2 of the second pixel unit 112.

As shown in FIG. 4A, after detecting that the light emitting element ED disposed in the third sub-pixel unit B1 of the first pixel unit 111 is defective, the light emitting element ED disposed in the third sub-pixel unit B1 of the first pixel unit 111 is removed (not shown). Next, conductive adhesives CA are provided between the pixel electrode PE of the third sub-pixel unit B1 of the first pixel unit 111 and the repair electrode FE of the first repair unit F1, on the repair electrode FE of the first repair unit F1, and on the common electrode CE, and then a light emitting element for replacement is provided on the aforementioned conductive adhesives CA (not shown).

As shown in FIG. 4B, after detecting that the light emitting element ED disposed in the third sub-pixel unit B2 of the second pixel unit 112 is defective, the light emitting element ED disposed in the third sub-pixel unit B2 of the second pixel unit 112 is removed (not shown). Next, conductive adhesives CA are provided between the pixel electrode PE of the third sub-pixel unit B2 of the second pixel unit 112 and the repair electrode FE of the first repair unit F1, on the repair electrode FE of the first repair unit F1, and on the common electrode CE, and then a light emitting element for replacement is provided on the aforementioned conductive adhesives CA (not shown).

In addition, as shown in FIG. 2A, due to the layout position of the second repair unit F2, the first sub-pixel unit R2 of the third pixel unit 113, the third sub-pixel unit B3 of the third pixel unit 113 and the third sub-pixel unit B4′ of the fourth pixel unit 114 is the same as the layout position of the first repair unit F1, the first sub-pixel unit R1 of the first pixel unit 111, the third sub-pixel unit B2 of the second pixel unit 112, and the third sub-pixel B1 of the first pixel unit 111, so the repair method of the second repair unit F2 to repair the corresponding sub-pixel unit is the same as the repair method of the first repair unit F1 to repair the corresponding sub-pixel unit. Therefore, the same features are not repeated here.

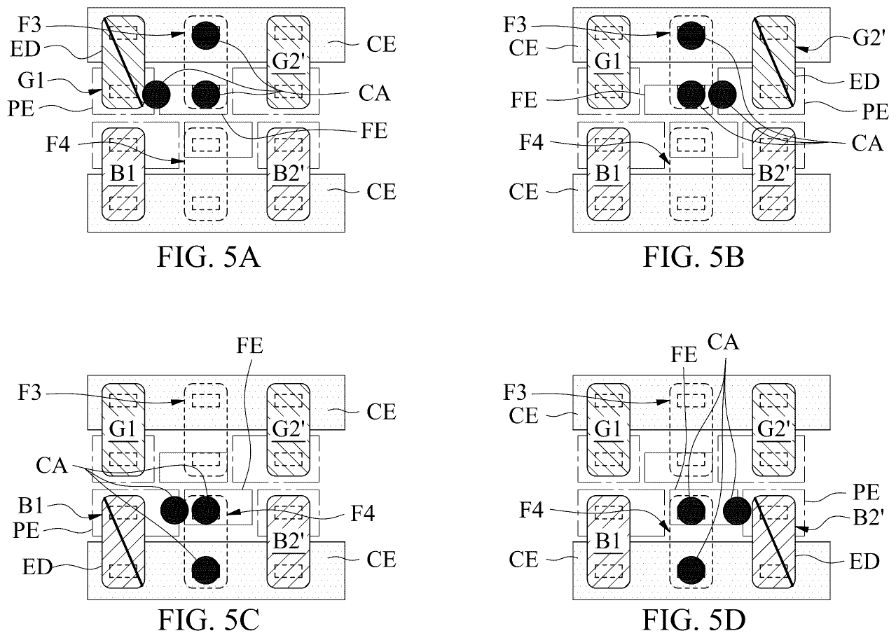

FIG. 5A to FIG. 5D are schematic diagrams of a repair method for a display device according to at least another embodiment of the present disclosure. FIG. 5A and FIG. 5B illustrate how the third repair unit F3 repairs the second sub-pixel unit G1 of the first pixel unit 111 and the second sub-pixel unit G2′ of the second pixel unit 112, respectively. FIG. 5C and FIG. 5D illustrate how the fourth repair unit F4 repairs the third sub-pixel unit B1 of the first pixel unit 111 and the third sub-pixel unit B2′ of the second pixel unit 112, respectively.

As shown in FIG. 5A, after detecting that the light emitting element ED disposed in the second sub-pixel unit G1 of the first pixel unit 111 is defective, the light emitting element ED disposed in the second sub-pixel unit G1 of the first pixel unit 111 is removed (not shown). Next, conductive adhesives CA are provided between the pixel electrode PE of the second sub-pixel unit G1 of the first pixel unit 111 and the repair electrode FE of the third repair unit F3, on the repair electrode FE of the third repair unit F3, and on the common electrode CE, and then a light emitting element for replacement is provided on the aforementioned conductive adhesives CA (not shown).

As shown in FIG. 5B, after detecting that the light emitting element ED disposed in the second sub-pixel unit G2′ of the second pixel unit 112 is defective, the light emitting element ED disposed in the second sub-pixel unit G2′ of the second pixel unit 112 is removed (not shown). Next, conductive adhesives CA are provided between the pixel electrode PE of the second sub-pixel unit G2′ of the second pixel unit 112 and the repair electrode FE of the third repair unit F3, on the repair electrode FE of the third repair unit F3, and on the common electrode CE, and then a light emitting element for replacement is provided on the aforementioned conductive adhesives CA (not shown).

As shown in FIG. 5C, after detecting that the light emitting element ED disposed in the third sub-pixel unit B1 of the first pixel unit 111 is defective, the light emitting element ED disposed in the third sub-pixel unit B1 of the first pixel unit 111 is removed (not shown). Next, conductive adhesives CA are provided between the pixel electrode PE of the third sub-pixel unit B1 of the first pixel unit 111 and the repair electrode FE of the fourth repair unit F4, on the repair electrode FE of the fourth repair unit F4, and on the common electrode CE, and then a light emitting element for replacement is provided on the aforementioned conductive adhesives CA (not shown).

As shown in FIG. 5D, after detecting that the light emitting element ED disposed in the third sub-pixel unit B2′ of the second pixel unit 112 is defective, the light emitting element ED disposed in the third sub-pixel unit B2′ of the second pixel unit 112 is removed (not shown). Next, conductive adhesives CA are provided between the pixel electrode PE of the third sub-pixel unit B2′ of the second pixel unit 112 and the repair electrode FE of the fourth repair unit F4, on the repair electrode FE of the fourth repair unit F4, and on the common electrode CE, and then a light emitting element for replacement is provided on the aforementioned conductive adhesives CA (not shown).

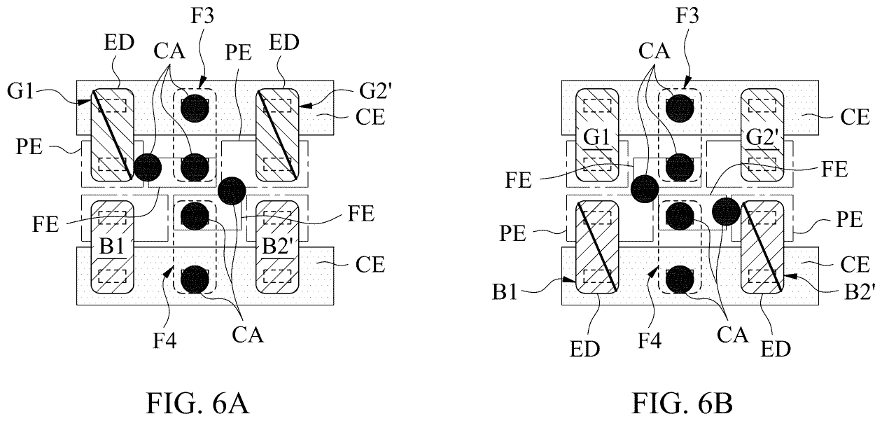

FIG. 6A and FIG. 6B are schematic diagrams of a repair method for a display device according to at least another embodiment of the present disclosure. FIG. 6A illustrates how the third repair unit F3 and the fourth repair unit F4 simultaneously repair the second sub-pixel unit G1 of the first pixel unit 111 and the second sub-pixel unit G2′ of the second pixel unit 112, respectively. FIG. 6B illustrates how the third repair unit F3 and the fourth repair unit F4 simultaneously repair the third sub-pixel unit B1 of the first pixel unit 111 and the third sub-pixel unit B2′ of the second pixel unit 112, respectively.

As shown in FIG. 6A, after detecting that the light emitting element ED disposed in the second sub-pixel unit G1 of the first pixel unit 111 and the light emitting element ED disposed in the second sub-pixel unit G2′ of the second pixel unit 112 are defective, the light emitting element ED disposed in the second sub-pixel unit G1 of the first pixel unit 111 and the light emitting element ED disposed in the second sub-pixel unit G2′ of the second pixel unit 112 are removed (not shown). Next, conductive adhesives CA are provided between the pixel electrode PE of the second sub-pixel unit G1 of the first pixel unit 111 and the repair electrode FE of the third repair unit F3, on the repair electrode FE of the third repair unit F3, and on the common electrode CE, and then a light emitting element for replacement is provided on the aforementioned conductive adhesives CA (not shown). Furthermore, conductive adhesives CA are provided between the pixel electrode PE of the second sub-pixel unit G2′ of the second pixel unit 112 and the repair electrode FE of the fourth repair unit F4, on the repair electrode FE of the fourth repair unit F4, and on the common electrode CE, and then a light emitting element for replacement is provided on the aforementioned conductive adhesives CA (not shown).

As shown in FIG. 6B, after detecting that the light emitting element ED disposed in the third sub-pixel unit B1 of the first pixel unit 111 and the light emitting element ED disposed in the third sub-pixel unit B2′ of the second pixel unit 112 are defective, the light emitting element ED disposed in the third sub-pixel unit B1 of the first pixel unit 111 and the light emitting element ED disposed in the third sub-pixel unit B2′ of the second pixel unit 112 are removed (not shown). Next, conductive adhesives CA are provided between the pixel electrode PE of the third sub-pixel unit B1 of the first pixel unit 111 and the repair electrode FE of the third repair unit F3, on the repair electrode FE of the third repair unit F3, and on the common electrode CE, and then a light emitting element for replacement is provided on the aforementioned conductive adhesives CA (not shown). Furthermore, conductive adhesives CA are provided between the pixel electrode PE of the third sub-pixel unit B2′ of the second pixel unit 112 and the repair electrode FE of the fourth repair unit F4, on the repair electrode FE of the fourth repair unit F4, and on the common electrode CE, and then a light emitting element for replacement is provided on the aforementioned conductive adhesives CA (not shown).

In addition, as shown in FIG. 2A, due to the layout position of the fifth repair unit F5, the second sub-pixel unit G3 of the third pixel unit 113, the second sub-pixel unit G4 of the fourth pixel unit 114 and the third sub-pixel unit B4 of the fourth pixel unit 114 is the same as the layout position of the third repair unit F3, the second sub-pixel unit G2′ of the second pixel unit 112, the second sub-pixel unit G1 of the first pixel unit 111, and the third sub-pixel B1 of the first pixel unit 111, so the repair method of the fifth repair unit F5 to repair the corresponding sub-pixel unit is the same as the repair method of the third repair unit F3 to repair the corresponding sub-pixel unit. Therefore, the same features are not repeated here.

Due to the layout position of the sixth repair unit F6, the second sub-pixel unit G3 of the third pixel unit 113, the third sub-pixel unit B3 of the third pixel unit 113 and the third sub-pixel unit B4 of the fourth pixel unit 114 is the same as the layout position of the fourth repair unit F4, the second sub-pixel unit G2′ of the second pixel unit 112, the third sub-pixel unit B2′ of the second pixel unit 112, and the third sub-pixel B1 of the first pixel unit 111, so the repair method of the sixth repair unit F6 to repair the corresponding sub-pixel unit is the same as the repair method of the fourth repair unit F4 to repair the corresponding sub-pixel unit. Therefore, the same features are not repeated here.

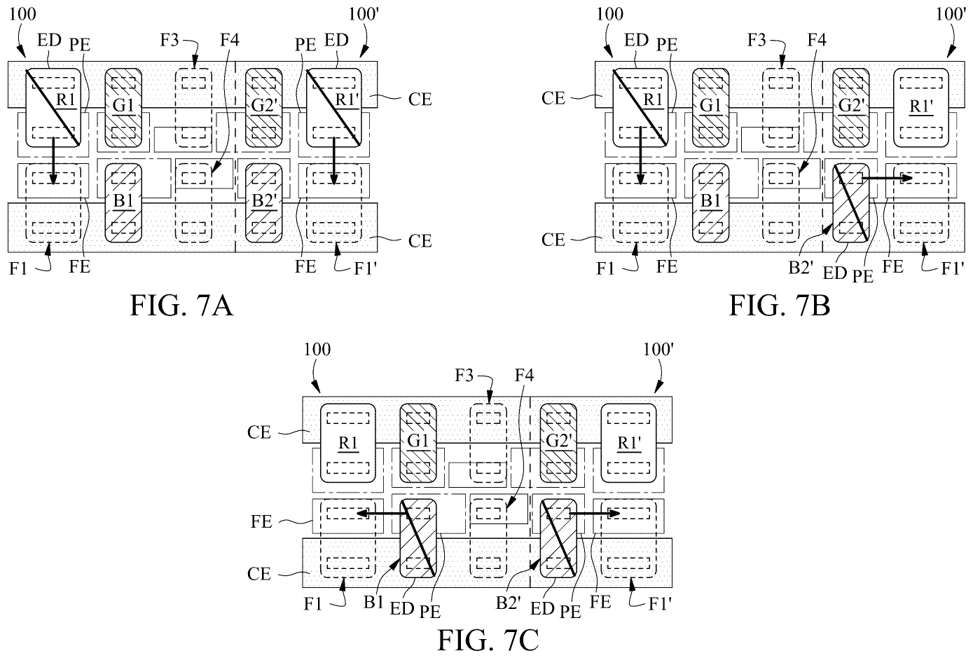

FIG. 7A to FIG. 7C are schematic diagrams of a repair method for a display device according to at least another embodiment of the present disclosure. FIG. 7A illustrates a method of selecting a repair unit when two adjacent layout units 100, 100′ with light emitting elements ED disposed in the first sub-pixel units R1, R1′ are both detected to be defective, and both need to be repaired. FIG. 7B illustrates a method of selecting a repair unit when two adjacent layout units 100, 100′ with the light emitting element ED disposed in the first sub-pixel unit R1 and the light emitting element ED disposed in the third sub-pixel unit B2′ are both detected to be defective, and both need to be repaired. FIG. 7C illustrates a method of selecting a repair unit when two adjacent layout units 100, 100′ with light emitting elements ED disposed in the third sub-pixel units B1, B2′ are both detected to be defective, and both need to be repaired.

As shown in FIG. 7A, when the light emitting elements ED disposed in the first sub-pixel units R1, R1′ in two adjacent layout units 100, 100′ are both detected to be defective, as indicated by the arrows in the figure, select the first repair unit F1 in the layout unit 100 to repair the first sub-pixel unit R1, and the first sub-pixel unit R1′ is repaired by the first repair unit F1′ in the layout unit 100′. In this way, if the light emitting elements ED disposed in the second sub-pixel units G1, G2′ and/or the third sub-pixel units B1, B2′ in two adjacent layout units 100, 100′ are detected to be defective, the third repair unit F3 and/or the fourth repair unit F4 in the layout unit 100 are still can be used for repairing.

As shown in FIG. 7B, when the light emitting elements ED disposed in the first sub-pixel unit R1 and in the third sub-pixel unit B2′ in two adjacent layout units 100, 100′ are both detected to be defective, as indicated by the arrows in the figure, select the first repair unit F1 in the layout unit 100 to repair the first sub-pixel unit R1, and the third sub-pixel unit B2′ is repaired by the first repair unit F1′ in the layout unit 100′. In this way, if the light emitting elements ED disposed in the second sub-pixel units G1, G2′ and/or the third sub-pixel unit B1 in two adjacent layout units 100, 100′ are detected to be defective, the third repair unit F3 and/or the fourth repair unit F4 in the layout unit 100 are still can be used for repairing.

As shown in FIG. 7C, when the light emitting elements ED disposed in the third sub-pixel units B1, B2′ in two adjacent layout units 100, 100′ are both detected to be defective, as indicated by the arrows in the figure, select the first repair unit F1 in the layout unit 100 to repair the third sub-pixel unit B1, and the third sub-pixel unit B2′ is repaired by the first repair unit F1′ in the layout unit 100′. In this way, if the light emitting elements ED disposed in the second sub-pixel units G1, G2′ in two adjacent layout units 100, 100′ are detected to be defective, the third repair unit F3 and/or the fourth repair unit F4 in the layout unit 100 are still can be used for repairing.

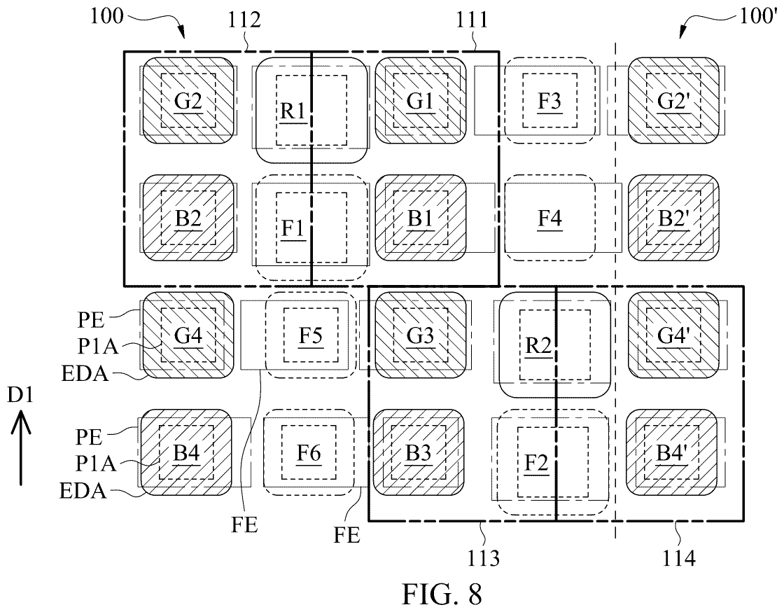

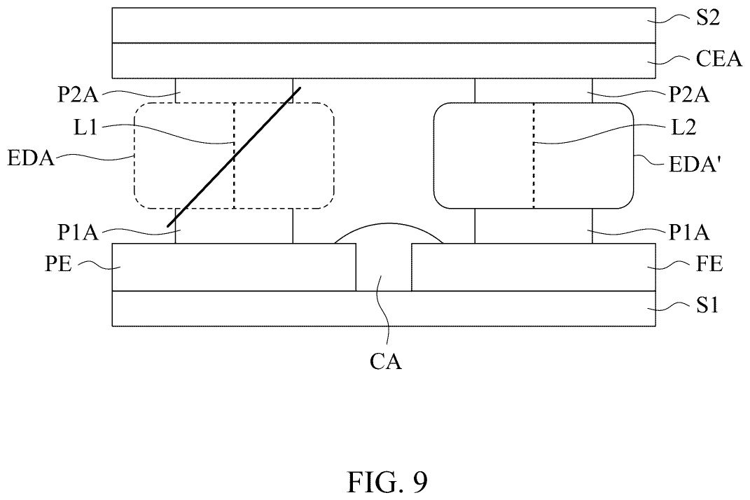

FIG. 8 is an enlarged diagram of partial area of a display device according to at least another embodiment of the present disclosure. FIG. 9 is a schematic partial cross-sectional diagram of a display device according to at least another embodiment of the present disclosure. The structures and the relative positions of most elements in the embodiment of FIG. 8 and the embodiment of FIG. 2A are the same, so the same features are not repeated here. The main difference between the two embodiments is that the light emitting element EDA of the embodiment of FIG. 8 is a vertical light emitting element, and the light emitting element ED of the embodiment of FIG. 2A is a lateral light emitting element.

In detail, as shown in FIG. 8 and FIG. 9, the pixel electrode PE and the repair electrode FE are disposed on a first substrate S1, the common electrode CEA is disposed on a second substrate S2 opposite the first substrate S1, and each of the light emitting elements EDA, EDA′ includes the first pad P1A electrically connected to the pixel electrode PE or the repair electrode FE, and the second pad P2A electrically connected to the common electrode CEA. The shortest connecting lines L1, L2 between the first pad P1A and the second pad P2A of each of the light emitting elements EDA, EDA′ are substantially parallel to each other, that is, both are substantially parallel to the normal line of the first substrate S1.

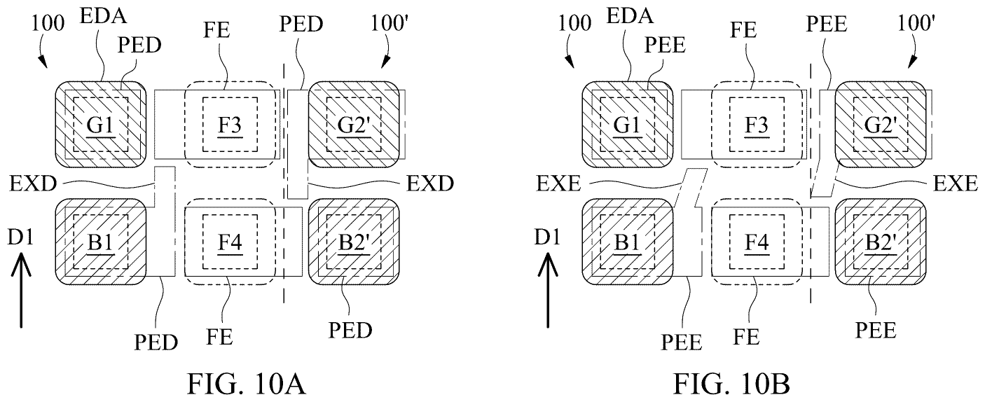

FIG. 10A and FIG. 10B are enlarged diagrams of partial areas of display devices according to at least another embodiment of the present disclosure. Referring to FIG. 10A, in each layout unit 100, 100′, two of the pixel electrodes PED (e.g. the pixel electrodes PED of the third sub-pixel units B1, B2′ and the second sub-pixel units G1, G2′) are arranged adjacently in the first direction D1, and a portion of two of the pixel electrodes PED (e.g. the pixel electrodes PED of the third sub-pixel units B1, B2′ and the second sub-pixel units G1, G2′) do not overlap in the first direction D1.

Taking the third sub-pixel unit B1 and the second sub-pixel unit G1 as an example, one of the two pixel electrodes PED (e.g. the pixel electrode PED of the third sub-pixel unit B1) includes an extending part EXD, and the extending part EXD substantially extends in the first direction D1. Taking the third sub-pixel unit B2′ and the second sub-pixel unit G2′ as an example, one of the two pixel electrodes PED (e.g. the pixel electrode PED of the second sub-pixel unit G2′) includes an extending part EXD, and the extending part EXD substantially extends in a direction that is 180 degrees from the first direction D1.

Referring to FIG. 10B, the difference between the embodiment of FIG. 10B and the embodiment of FIG. 10A is that, taking the third sub-pixel unit B1 and the second sub-pixel unit G1 as an example, one of the two pixel electrodes PEE (e.g. the pixel electrode PEE of the third sub-pixel unit B1) includes an extending part EXE, and the extending part EXE substantially extends in a direction that is greater than 0 degrees and less than 90 degrees from the first direction D1. Taking the third sub-pixel unit B2′ and the second sub-pixel unit G2′ as an example, one of the two pixel electrodes PEE (e.g. the pixel electrode PEE of the second sub-pixel unit G2′) includes an extending part EXE, and the extending part EXE substantially extends in a direction that is greater than 180 degrees and less than 270 degrees from the first direction D1.

Through the design that the pixel electrodes include extending parts, the risk of the repair unit short-circuiting with other sub-pixel units when repairing oblique sub-pixel unit can be reduced. Furthermore, the above-mentioned design of the pixel electrodes including extending parts can shorten the distance between the pixel electrode and the repair electrode, thereby improving the repair efficiency. For example, there is no need to dispensing conductive adhesives multiple times between the pixel electrode and the repair electrode.

In summary, in at least one embodiment of the display device of the present disclosure, one of the repair units is used to repair any one of three of the sub-pixel units, and in each of the layout units, the number of the repair electrodes is less than the number of the pixel electrodes, so the number of the repair units and the number of the repair electrodes can be reduced, thereby increasing the display area ratio and the resolution. Furthermore, since the shortest connecting lines between the first pads electrically connected to the pixel electrodes or the repair electrodes and the second pads electrically connected to the common electrodes are parallel to each other, that is, the light emitting elements are arranged in an array of regular rows and columns, which can reduce the difficulty of manufacturing and repair and is suitable for mass transfer.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A display device, comprising:
a plurality of layout units, arranged in array and comprising:
a plurality of pixel units, wherein each of the pixel units comprises a plurality of sub-pixel units, and each of the sub-pixel units comprises a pixel electrode;
a plurality of repair units, wherein one of the repair units is used to repair any one of three of the sub-pixel units, and each of the repair units comprises a repair electrode, wherein in each of the layout units, a number of the repair electrodes is smaller than a number of the pixel electrodes; and
a common electrode; and
a plurality of light emitting elements, disposed in the layout units, wherein each of the light emitting elements comprises a first pad electrically connected to the pixel electrode or the repair electrode, and a second pad electrically connected to the common electrode, wherein the light emitting elements have a shortest connecting line between the first pad and the second pad apiece while the shortest connecting lines are parallel to each other.

2. The display device of claim 1, wherein in each of the layout units, the sub-pixel units and the repair units are arranged in array.

3. The display device of claim 2, wherein each of the pixel units comprises a first sub-pixel unit, a second sub-pixel unit and a third sub-pixel unit, the pixel units comprise a first pixel unit, a second pixel unit, a third pixel unit and a fourth pixel unit, wherein in two of the layout units adjacent to each other, the first pixel unit and the second pixel unit of one of the two of the layout units share one of the first sub-pixel units, and the third pixel unit of the one of the two of the layout units and the fourth pixel unit of the other of the two of the layout unit share another of the first sub-pixel units.

4. The display device of claim 3, wherein the repair units comprise a first repair unit for repairing one of the first sub-pixel unit of the first pixel unit of the one of the two of the layout units, the third sub-pixel unit of the first pixel unit of the one of the two of the layout units, and the third sub-pixel unit of the second pixel unit of the one of the two of the layout units.

5. The display device of claim 4, wherein the repair units comprise a second repair unit for repairing one of the first sub-pixel unit of the third pixel unit of the one of the two of the layout units, the third sub-pixel unit of the third pixel unit of the one of the two of the layout units, and the third sub-pixel unit of the fourth pixel unit of the other of the two of the layout units.

6. The display device of claim 5, wherein the repair units comprise a third repair unit for repairing one of the second sub-pixel unit of the first pixel unit of the one of the two of the layout units, the third sub-pixel unit of the first pixel unit of the one of the two of the layout units, and the second sub-pixel unit of the second pixel unit of the other of the two of the layout units.

7. The display device of claim 6, wherein the repair units comprise a fourth repair unit for repairing one of the third sub-pixel unit of the first pixel unit of the one of the two of the layout units, the second sub-pixel unit of the second pixel unit of the other of the two of the layout units, and the third sub-pixel unit of the second pixel unit of the other of the two of the layout units.

8. The display device of claim 7, wherein the repair units comprise a fifth repair unit for repairing one of the second sub-pixel unit of the third pixel unit of the one of the two of the layout units, the second sub-pixel unit of the fourth pixel unit of the one of the two of the layout units, and the third sub-pixel unit of the fourth pixel unit of the one of the two of the layout units.

9. The display device of claim 8, wherein the repair units comprise a sixth repair unit for repairing one of the second sub-pixel unit of the third pixel unit of the one of the two of the layout units, the third sub-pixel unit of the third pixel unit of the one of the two of the layout units, and the third sub-pixel unit of the fourth pixel unit of the one of the two of the layout units.

10. The display device of claim 1, wherein in each of the layout units, two of the repair electrodes are arranged adjacently in a first direction, and a portion of the two of the repair electrodes do not overlap in the first direction.

11. The display device of claim 10, wherein each of the two of the repair electrodes comprises an extending part, one of the two extending parts extends in the first direction, and the other of the two extending parts extends in a direction that is 180 degrees from the first direction.

12. The display device of claim 10, wherein each of the two of the repair electrodes comprises an extending part, one of the two extending parts extends in a direction that is greater than 0 degrees and less than 90 degrees from the first direction, and the other of the two extending parts extends in a direction that is greater than 180 degrees and less than 270 degrees from the first direction.

13. The display device of claim 1, wherein in each of the layout units, two of the pixel electrodes are arranged adjacently in a first direction, and a portion of the two of the pixel electrodes do not overlap in the first direction.

14. The display device of claim 13, wherein one of the two of the pixel electrodes comprises an extending part, and the extending parts extends in the first direction or in a direction that is 180 degrees from the first direction.

15. The display device of claim 13, wherein one of the two of the pixel electrodes comprises an extending part, and the extending part extends in a direction that is greater than 0 degrees and less than 90 degrees from the first direction or in a direction that is greater than 180 degrees and less than 270 degrees from the first direction.

16. The display device of claim 1, further comprising:
a first substrate; and
a second substrate, disposed opposite to the first substrate, wherein the pixel electrodes and the repair electrodes are disposed on the first substrate, and the common electrode is disposed on the second substrate.

17. A display device, comprising:
a plurality of layout units, arranged in array and comprising:
a plurality of pixel units, wherein each of the pixel units comprises a plurality of sub-pixel units, and each of the sub-pixel units comprises a pixel electrode;
a plurality of repair units, wherein one of the repair units is used to repair any one of three of the sub-pixel units, and each of the repair units comprises a repair electrode, wherein in each of the layout units, a ratio of a number of the repair electrodes to a number of the pixel electrodes is 0.6; and
a common electrode; and
a plurality of light emitting elements, disposed in the layout units, wherein each of the light emitting elements comprises a first pad electrically connected to the pixel electrode or the repair electrode, and a second pad electrically connected to the common electrode, wherein the light emitting elements have a shortest connecting line between the first pad and the second pad apiece while the shortest connecting lines are parallel to each other.

18. The display device of claim 17, wherein in each of the layout units, the sub-pixel units and the repair units are arranged in array.

19. The display device of claim 17, wherein each of the pixel units comprises a first sub-pixel unit, a second sub-pixel unit and a third sub-pixel unit, the pixel units comprise a first pixel unit, a second pixel unit, a third pixel unit and a fourth pixel unit, wherein in two of the layout units adjacent to each other, the first pixel unit and the second pixel unit of one of the two of the layout units share one of the first sub-pixel units, and the third pixel unit of the one of the two of the layout units and the fourth pixel unit of the other of the two of the layout unit share another of the first sub-pixel units.

20. The display device of claim 19, wherein a luminous area of the light emitting element disposed in the first sub-pixel unit is larger than a luminous area of the light emitting element disposed in the second sub-pixel unit, and is larger than a luminous area of the light emitting element disposed in the third sub-pixel unit.
